(19) United States
(12) Patent Application Publication
(10) Pub. No.: US 2025/0199180 A1
(43) Pub. Date: Jun. 19, 2025

(54) PHOTOELECTRIC CONVERSION DEVICE AND METHOD OF CONTROLLING PHOTOELECTRIC CONVERSION DEVICE

(71) Applicant: CANON KABUSHIKI KAISHA, Tokyo (JP)

(72) Inventor: TAKEAKI ITSUJI, Kanagawa (JP)

(21) Appl. No.: 18/978,975

(22) Filed: Dec. 12, 2024

(30) Foreign Application Priority Data
Dec. 18, 2023 (JP) 2023-212996

(51) Int. Cl. G01S 17/88; G01S 17/10; H10F 39/10

(52) U.S. Cl. CPC G01S 17/88; G01S 17/10; H10F 39/103

(57) ABSTRACT

A conversion device includes a light detection unit including a photoelectric conversion element, a control unit that controls the light detection unit and a light source device, and a processing unit that processes a signal indicating a detection result of incident light to the light detection unit. The control unit controls the light source device so that pulsed light is emitted from the light source device, and controls the light detection unit so as to detect light incident on the light detection unit in a time window corresponding to a certain distance. The processing unit outputs a light detection frame constituted by a 1-bit signal by calculating a logical sum of signals that are output from the light detection unit and indicate detection results, the number of the signals corresponding to a light emission number. The light emission number varies depending on distances to be measured.

### BACKGROUND

### Technical Field

The aspect of the embodiments relates to a photoelectric conversion device and a method of controlling the photoelectric conversion device.

### Description of the Related Art

Japanese Patent Application Laid-Open No. 2022-002288 discloses a photoelectric conversion device having a pixel structure in which crosstalk between adjacent avalanche diodes is suppressed. Japanese Patent Application Laid-Open No. 2022-002288 discloses a time gating time-of-flight (ToF) distance image sensor. In the time gating ToF, a distance between an object and the photoelectric conversion device is measured by sweeping a time position of a gate window that is a photon detection period and acquiring a distribution of photon count values at each time position. When the distance image sensor disclosed in Japanese Patent Application Laid-Open No. 2022-002288 is driven, irradiation of laser pulsed light and detection of light are performed a plurality of times in measurement in each gate window.

In the technology of the time gating ToF disclosed in Japanese Patent Application Laid-Open No. 2022-002288, a reduction in power consumption accompanying a plurality of measurements may be required.

### SUMMARY

According to an aspect of the embodiments, there is provided a conversion device including a light detection unit including a photoelectric conversion element, a control unit configured to control the light detection unit and a light source device, and a processing unit configured to process a signal indicating a detection result of incident light to the light detection unit. In a first measurement, the control unit controls the light source device so that first pulsed light of a first light emission number is emitted from the light source device, and controls the light detection unit so as to detect light incident on the light detection unit in a first time window corresponding to a first distance. In the first measurement, the processing unit calculates a logical sum on first signals that are output from the light detection unit and indicate detection results to output a first light detection frame constituted by a 1-bit signal, the number of the first signals corresponding to the first light emission number. In a second measurement, the control unit controls the light source device so that second pulsed light of a second light emission number is emitted from the light source device, and controls the light detection unit so as to detect light incident on the light detection unit in a second time window corresponding to a second distance. In the second measurement, the processing unit calculates a logical sum on second signals that are output from the light detection unit and indicate detection results to output a second light detection frame constituted by a 1-bit signal, the number of the second signals corresponding to the second light emission number.

According to another aspect of the embodiments, there is provided a method of controlling a conversion device having a light detection unit including a photoelectric conversion element. The method includes detecting light incident on the light detection unit in a first time window corresponding to a first distance, when first pulsed light of a first light emission number is emitted from a light source device, outputting a first light detection frame constituted by a 1-bit signal by calculating a logical sum on first signals that are output from the light detection unit and indicate detection results, the number of the first signals corresponding to the first light emission number, detecting light incident on the light detection unit in a second time window corresponding to a second distance, when second pulsed light of a second light emission number is emitted from the light source device, and outputting a second light detection frame constituted by a 1-bit signal by calculating a logical sum on second signals that are output from the light detection unit and indicate detection results, the number of the second signals corresponding to the second light emission number.

Further features of the disclosure will become apparent from the following description of exemplary embodiments with reference to the attached drawings.

### BRIEF DESCRIPTION OF THE DRAWINGS

FIG. 1A is a graph illustrating an operation and a problem of a time gating ToF type ranging device.

FIG. 1B is a graph illustrating the operation and the problem of the time-gating ToF type ranging device.

FIG. 1C is a graph illustrating the operation and the problem of the time gating ToF type ranging device.

FIG. 2 is a block diagram illustrating a configuration example of a ranging device according to a first embodiment.

FIG. 3 is a diagram schematically illustrating an outline of an operation of the ranging device according to the first embodiment.

FIG. 4A is a graph illustrating an effect of adjusting a light emission number.

FIG. 4B is a graph illustrating the effect of adjusting the light emission number.

FIG. 5 is a flowchart illustrating an operation of the ranging device according to the first embodiment.

FIG. 6 is a graph illustrating an example of calculation of the light emission number according to the first embodiment.

FIG. 7 is a diagram schematically illustrating an outline of an operation of a ranging device according to a second embodiment.

FIG. 8 is a graph illustrating an example of calculation of the light emission number in a third embodiment.

FIG. 9 is a diagram schematically illustrating an outline of an operation of a ranging device according to a fourth embodiment.

FIG. 10 is a schematic diagram illustrating an overall configuration of a photoelectric conversion device according to a fifth embodiment.

FIG. 11 is a schematic block diagram illustrating a configuration example of a sensor substrate according to the fifth embodiment.

FIG. 12 is a schematic block diagram illustrating a configuration example of a circuit substrate according to the fifth embodiment.

FIG. 13 is a schematic block diagram illustrating a configuration example of one pixel of a photoelectric conversion unit and a pixel signal processing unit according to the fifth embodiment.

FIG. 14A is a diagram illustrating an operation of an avalanche photodiode according to the fifth embodiment.

FIG. 14B is a diagram illustrating the operation of the avalanche photodiode according to the fifth embodiment.

FIG. 14C is a diagram illustrating the operation of the avalanche photodiode according to the fifth embodiment.

FIG. 15A is a schematic diagram of equipment according to a sixth embodiment.

FIG. 15B is a schematic diagram of the equipment according to the sixth embodiment.

### DESCRIPTION OF THE EMBODIMENTS

Hereinafter, embodiments of the present disclosure will be described with reference to the drawings. The same or corresponding elements are denoted by the same reference numerals throughout the several drawings, and the description thereof may be omitted or simplified.

### First Embodiment

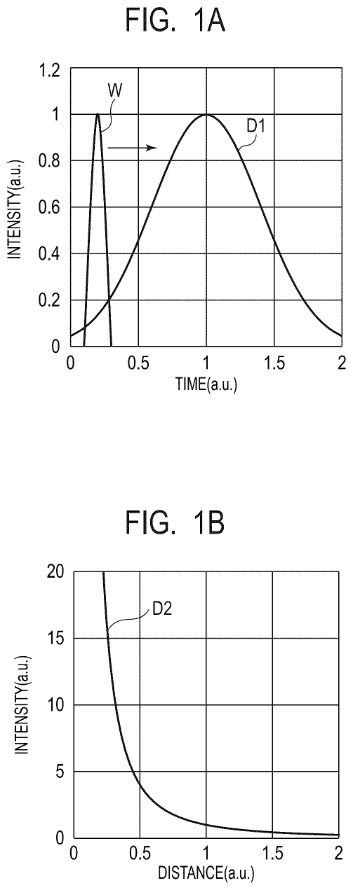

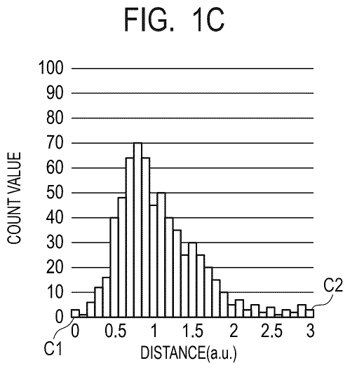

Prior to the description of the ranging device of the present embodiment, an overall image of an operation and a problem of a time gating time-of-flight (ToF) type ranging device will be described. FIGS. 1A, 1B, and 1C are graphs illustrating an operation and a problem of the time gating ToF type ranging device.

The ranging device repeatedly emits laser pulsed light to an object. Then, the ranging device acquires time information indicating a time difference from a time when the laser pulsed light is emitted to a time when the reflected pulsed light from the object reaches the ranging device. The ranging device acquires the distance from the ranging device to the object by converting the time information into distance information. In the time gating ToF type ranging device, the ranging device detects the reflected pulsed light reaching the ranging device within a period of a time window.

FIG. 1A is a graph schematically illustrating a relationship between an intensity distribution of reflected light and a time window. The horizontal axis of FIG. 1A represents time in arbitrary units, and the vertical axis of FIG. 1A represents intensity in arbitrary units. A time window W in FIG. 1A schematically illustrates a photon detection period in the ranging device. An intensity distribution D1 of FIG. 1A schematically illustrates an intensity distribution of the reflected light incident on the ranging device. The ranging device measures the number of detections of photons incident on the ranging device within the period of the time window W by sweeping the time window W with respect to time.

The ranging device converts time information based on a time position of the time window W obtained as described above into measurement distance information. The ranging device stores the time information or the measurement distance and the number of photon detections in association with each other as a frequency distribution. FIG. 1C illustrates an example of the frequency distribution obtained in this way. The horizontal axis of FIG. 1C represents a distance in arbitrary units, and the vertical axis of FIG. 1C represents a count value corresponding to the number of photon detections.

The count value obtained by measuring the number of photon detections in the period of the time window W does not necessarily coincide with the number of incident photons. In the measurement of the number of photon detections, processing of counting a value of 1-bit indicating whether or not a photon enters the ranging device within the period of the time window W is repeatedly performed a plurality of times. In the present specification, an event that a photon is incident on a ranging device is also referred to as a photon incident event. The number of photon detections can also be read as the number of photon incident events.

In the measurement of the photon incident events in the time window W, the laser pulsed light is emitted multiple times. The higher the number of times the laser pulsed light is emitted, the higher the probability of incidence of photons in the time window W, that is, the higher the probability that the ranging device detects photon incident events. By sweeping the time window W, a plurality of count values are measured, including the number of detections of photons (for example, a count value C1 in FIG. 1C) incident during a period of a first time window corresponding to a first distance and the number of detections of photons (for example, a count value C2 in FIG. 1C) incident during a period of a second time window corresponding to a second distance. By obtaining a distance (peak position) corresponding to the maximum value of the count values from the frequency distribution obtained in this manner, the ranging device acquires a distance from the ranging device to the object.

The generation of the frequency distribution is performed by sampling measurements by sweeping the period of the time window W. That is, the frequency distribution approximates a result of a convolution operation of a waveform of the time window W and an intensity distribution D2 of the reflected light from the object in FIG. 1A.

FIG. 1B is a graph illustrating a relationship between the distance and intensity of emitted laser pulsed light. The horizontal axis in FIG. 1B represents a distance in arbitrary units, and the vertical axis in FIG. 1B represents intensity in arbitrary units. An intensity distribution D2 of FIG. 1B illustrates a relationship between a flight distance of light and intensity of light. As illustrated in FIG. 1B, the intensity of light is inversely proportional to the square of the distance. Therefore, the number of photons incident in the time window W varies depending on the measurement distance. For example, the shorter the measurement distance, the larger the number of photons incident in the time window W.

However, when a sufficient number of photons are incident in the time window W for the determination of the photon incident event, the number of photon detections (count value of the photon incident events) does not change with an increase in the number of photons. Therefore, in this case, there is a discrepancy between the number of photons and the number of photon detections. More specifically, when two or more photons are incident in the time window W by one emission of the laser pulsed light, there is a high possibility that there is a discrepancy between the number of photons and the number of photon detections. In the detection of the photon incident event, since the number of photon detections is determined to be one even when a plurality of photons are incident, the number of photon detections is estimated to be low with respect to the number of photons incident in the time window W. The influence of the distance dependency of the intensity illustrated in the intensity distribution D2 is also superimposed on the frequency distribution. According to the study of the inventor, the discrepancy between the number of photons and the number of photon detections tends to be particularly large in a region where the distance from the ranging device to the object is 10 m or less, and in one embodiment, the discrepancy is suppressed.

In a state where the discrepancy between the number of photons and the number of photon detections is large, when the contribution rate to the number of photon detections with respect to the increase in the number of light emissions of the laser pulsed light is extremely low, excess occurs in the number of light emissions of the laser pulse, and thus excess power is consumed. In the present embodiment, this problem is solved by appropriately adjusting the number of times the laser pulse is emitted according to the distance.

As a method different from the above-described time gating ToF type ranging device, there is a direct time-of-flight (dToF) type ranging device that directly measures a flight time of a photon. In the dToF type ranging device, the detector is kept in an exposure state for an assumed flight time, and the number of incident photons in each period is acquired by measuring the time when each photon is incident. Thus, the frequency distribution is generated. Compared to the dToF type ranging device, the time gating ToF type ranging device can control the exposure time of the detector by the period of the time window W. Since the influence of external light outside the period of the time window W can be suppressed, the time gating ToF type is a measurement method having high resistance to external light.

Hereinafter, a detailed configuration of a time gating ToF type ranging device according to the present embodiment will be described with reference to the drawings.

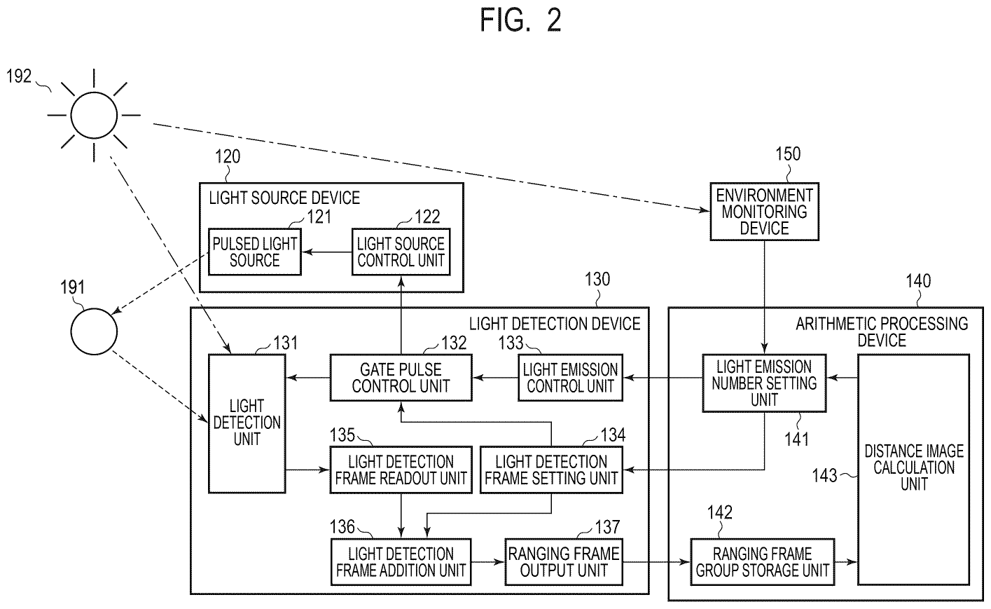

FIG. 2 is a block diagram illustrating a configuration example of a ranging device according to the present embodiment. The ranging device illustrated in FIG. 2 is a time gating ToF type ranging device. The ranging device includes a light source device 120, a light detection device 130, an arithmetic processing device 140, and an environment monitoring device 150. The light source device 120 includes a pulsed light source 121 and a light source control unit 122. The light detection device 130 includes a light detection unit 131, a gate pulse control unit 132, a light emission control unit 133, a light detection frame setting unit 134, a light detection frame readout unit 135, a light detection frame addition unit 136, and a ranging frame output unit 137. The arithmetic processing device 140 includes a light emission number setting unit 141, a ranging frame group storage unit 142, and a distance image calculation unit 143.

The pulsed light source 121 is a light source that generates laser pulsed light, and may be, for example, a solid-state laser or a semiconductor laser. When miniaturization or power saving of the light source device 120 is used, in one embodiment, the pulsed light source 121 is a semiconductor laser. In this case, the semiconductor laser may be an edge emitting laser (EEL) or a surface emitting laser (SEL). In one embodiment, the surface emitting laser is a vertical cavity surface emitting laser (VCSEL) when two-dimensional array or high-speed modulation is used. In the present embodiment, since modulation of the laser pulsed light is performed, in one embodiment, a vertical cavity surface emitting laser is used as the pulsed light source 121. The wavelength of the light output from the pulsed light source 121 may be, for example, a desired wavelength of 650 nm to 1080 nm, but is not limited thereto. For example, the wavelength of the light output from the pulsed light source 121 may be 1310 nm, 1550 nm, or the like used for medium-to-long distance communication.

The light source control unit 122 is a driving device that controls light emission of the pulsed light source 121. The light source control unit 122 outputs a first control pulse, which is a signal for driving the laser pulsed light, to the pulsed light source 121. The pulsed light source 121 controls light emission with reference to the first control pulse. For example, the pulsed light source 121 emits the laser pulsed light one or more times in response to one input of the first control pulse. In the present embodiment, the laser pulsed light is emitted once in response to one input of the first control pulse.

The light detection unit 131 is a semiconductor element that detects light. The light detection unit 131 includes one pixel or a plurality of pixels. The pixel includes a photoelectric conversion element. When the light detection unit 131 includes a plurality of pixels, the light detection unit 131 functions as an image sensor that detects a two-dimensional light distribution. The light detection unit 131 may include a photodiode, an avalanche photodiode, or the like as a photoelectric conversion element. The avalanche photodiode may be a single photon avalanche diode (SPAD). In the present embodiment, in order to detect a weak signal at a single photon level at high speed, it is assumed that a SPAD operating in a Geiger mode is used for the light detection unit 131. In one embodiment, the detection wavelength of the light detection unit 131 is to be coincident with the wavelength of the light emitted from the pulsed light source 121.

In order to perform highly accurate light detection, in one embodiment, measurement under an environment in which the intensity of noise light from an external noise source 192 is small is performed. The noise source 192 may be, for example, the sun. In order to reduce the influence of such noise light, in the present embodiment, a time gating ToF type that limits the exposure time is adopted as the configuration of the ranging device. The intensity distribution of noise light from the noise source 192 may follow the intensity distribution of black-body radiation. In this case, in order to avoid the peak of the intensity distribution of black-body radiation, in one embodiment, the detection wavelength of the light detection unit 131 is to be longer than the wavelength of visible light. For example, the wavelength of the light emitted from the pulsed light source 121 and the detection wavelength of the light detection unit 131 may be 1550 nm. In addition, in order to suppress the influence of the noise light, the light detection unit 131 may include a bandpass filter. The light detection unit 131 may include an imaging optical system. The imaging optical system forms an image of the reflected pulsed light from an object 191 on the light detection unit 131.

The gate pulse control unit 132 may be configured by a semiconductor integrated circuit such as a field programmable gate array (FPGA), or an application specific integrated circuit (ASIC). Similarly, the light emission control unit 133, the light detection frame setting unit 134, the light detection frame readout unit 135, the light detection frame addition unit 136, and the ranging frame output unit 137 may also be configured by a semiconductor integrated circuit such as an FPGA or an ASIC.

The gate pulse control unit 132 outputs a second control pulse for controlling the light detection operation of the light detection unit 131 to the light detection unit 131. The second control pulse is a control signal for setting a timing of a time window. The light detection unit 131 detects light during a period in which the second control pulse is enabled. The gate pulse control unit 132 is synchronized with the light source control unit 122, and indirectly controls the timing of the first control pulse. The gate pulse control unit 132 controls a time interval between the first control pulse and the second control pulse by controlling a phase of the second control pulse. That is, the gate pulse control unit 132 sets a time position of the time window in which the light detection is performed. The gate pulse control unit 132 controls the first control pulse and the second control pulse with reference to a light emission number (the number of times of light emission) output by the light emission control unit 133 and measurement distance information and measurement period information output by the light detection frame setting unit 134.

The light emission control unit 133 is an arithmetic processing circuit that outputs the light emission number of the light source device 120 to the gate pulse control unit 132. The light emission control unit 133 is also an interface circuit for the arithmetic processing device 140. According to the time position of the time window set by the gate pulse control unit 132, the light emission control unit 133 transmits information on the light emission number to the gate pulse control unit 132. The gate pulse control unit 132 monitors the light emission number, and stops outputting the first control pulse and the second control pulse after the light emission number reaches a predetermined number. Alternatively, the light emission control unit 133 may include a counter that counts the number of pulses of the first control pulse via the gate pulse control unit 132. In this case, after the number of the pulses of the first control pulse reaches a predetermined light emission number, the light emission control unit 133 outputs a signal for stopping the output of the first control pulse and the second control pulse to the gate pulse control unit 132.

The light detection frame setting unit 134 is an arithmetic processing circuit that outputs information on the time window to the gate pulse control unit 132. In other words, the light detection frame setting unit 134 outputs the time position, which corresponds to the measurement distance information, of the time window. The light detection frame setting unit 134 is also an interface circuit for the arithmetic processing device 140. The light detection frame setting unit 134 outputs a period of the light detection frame and the number of the light detection frames in each time window to the gate pulse control unit 132. The gate pulse control unit 132 determines signal patterns of the first control pulse and the second control pulse based on the information on the light emission number acquired from the light emission control unit 133 and the information on the period (measurement period information) of the light detection frames and the number of the light detection frames acquired from the light detection frame setting unit 134. In addition, the light detection frame setting unit 134 outputs information on the number of the light detection frames to the light detection frame addition unit 136. Details of the light detection frame will be described later. As described above, the gate pulse control unit 132, the light emission control unit 133, and the light detection frame setting unit 134 function as a control unit that controls the light detection unit 131 and the light source device 120.

The light detection frame readout unit 135 is an arithmetic processing circuit that outputs a light detection frame based on a signal output from the light detection unit 131. The light detection frame is an image obtained by reading an output signal from each pixel included in the light detection unit 131 and calculating a logical sum of a number of signals corresponding to the light emission number for each pixel. The signal corresponding to each pixel of the light detection frame is a 1-bit signal.

The light detection frame addition unit 136 is an arithmetic processing circuit that adds a predetermined number of light detection frames output from the light detection frame readout unit 135. More specifically, the light detection frame addition unit 136 refers to the number of frames output from the light detection frame setting unit 134, and acquires light detection frames corresponding to the number of frames from the light detection frame readout unit 135. Then, the light detection frame addition unit 136 generates pixel information by adding a plurality of pixel values of pixels at the same position among the plurality of light detection frames, and outputs the pixel information to the ranging frame output unit 137.

The ranging frame output unit 137 is an arithmetic processing circuit that generates a ranging frame from the pixel information output from the light detection frame addition unit 136. The ranging frame is a distribution image in which the number of incident events of photons at one measurement distance corresponding to the time window is a pixel value. The ranging frame output unit 137 is also an interface circuit that transfers the ranging frame from the light detection device 130 to the arithmetic processing device 140 in accordance with a predetermined image transfer protocol. As described above, the light detection frame readout unit 135, the light detection frame addition unit 136, and the ranging frame output unit 137 function as a processing unit that processes a signal indicating a detection result of incident light to the light detection unit.

The arithmetic processing device 140 may be configured by a semiconductor integrated circuit such as an FPGA or an ASIC. That is, the functions of the light emission number setting unit 141, the ranging frame group storage unit 142, and the distance image calculation unit 143 may be realized by a semiconductor integrated circuit such as an FPGA or an ASIC.

The light emission number setting unit 141 is an arithmetic processing circuit that sets the light emission number of the laser pulsed light used for distance measurement in each time window and outputs the light emission number to the light emission control unit 133. In addition, the light emission number setting unit 141 sets the number of the light detection frames output in the distance measurement in each time window, and outputs the number of the light detection frames to the light detection frame setting unit 134.

Details of the setting of the light emission number will be described. In the light emission number setting unit 141, a signal-to-noise ratio (SNR) of the ranging device in light detection is set in advance. The light emission number setting unit 141 obtains the measurement distance from the time position of the time window, and sets the value of the light emission number so that the SNR of the ranging device is included in a predetermined range based on the measurement distance.

The SNR is a value obtained by dividing the number of photons n included in the reflected pulsed light incident on the light detection unit 131 within the period of the time window by noise. When the number of photons incident on the light detection unit 131 within the period of the time window follows the Poisson distribution, the noise caused by the variation in the number of incident photons is √n.

The number of photons n is inversely proportional to the square of the distance between the object 191 and the light detection unit 131. As long as the measurement conditions are not changed, the number of photons n is proportional to the number of times the laser pulsed light is emitted.

The factor of noise with respect to the number of photons n includes noise light emitted from the noise source 192 in addition to noise caused by variation in the number of incident photons. When the noise source 192 exists sufficiently far from the ranging device as compared with the distance between the object 191 and the ranging device, the noise light incident within the period of the time window can be constant regardless of the distance. When there are a plurality of factors of noise as described above, the overall noise is calculated by the square root of the sum of squares of respective noises.

As described above, if the number of photons incident on the light detection unit 131 within the period of the time window can be defined under a certain measurement distance condition, the light emission number of the laser pulsed light can be calculated based on the measurement distance so that the value of the SNR is within a predetermined range. The number of incident photons per light emission can be calculated from, for example, the power of the laser pulsed light, the beam shape of the laser pulsed light, the reflectance of the object 191, the measurement distance between the object 191 and the light detection unit 131, and the angle of view of the light detection device 130. The light emission number setting unit 141 can calculate the light emission number based on a formula in which the power of the laser pulsed light, the reflectance of the object 191, the power of the noise light, the measurement distance between the object 191 and the light detection unit 131, and the like are variables. Further, in the setting of the light emission number, ray tracing may be combined with calculation of the number of photons.

The light emission number setting unit 141 may set the light emission number based on a light emission number table that stores the light emission number calculated in advance in the form of a lookup table. The light emission number table includes information in which the measurement distance and the light emission number are associated with each other. By using the light emission number table, it is not necessary to calculate the light emission number when changing the setting of the ranging frame. Therefore, the calculation load can be reduced, and the measurement operation can be speeded up.

The ranging frame group storage unit 142 includes an interface circuit that receives the information of the ranging frame output from the ranging frame output unit 137, and a storage unit that stores the information of the ranging frame. The ranging frame group storage unit 142 can output information of the stored ranging frames to the distance image calculation unit 143.

The distance image calculation unit 143 generates a distance image using the information of the ranging frames stored in the ranging frame group storage unit 142. For example, the distance image calculation unit 143 assigns color information to the distance information based on a lookup table, and outputs a distance image frame in which the distance image is represented by a two-dimensional color map. Further, for example, the distance image calculation unit 143 outputs a distance image frame in which the information of the ranging frame is represented by a three-dimensional point cloud map. The format of the distance image frame is not limited thereto. In addition, the distance image calculation unit 143 outputs information on the measurement distance used to generate the distance image frame to the light emission number setting unit 141. As described above, the ranging frame group storage unit 142 and the distance image calculation unit 143 function as a calculation unit that acquires distance information from the signal output from the light detection device 130.

The environment monitoring device 150 is a noise information acquisition device that measures noise light from the noise source 192 and outputs noise information indicating the amount of noise light received by the light detection unit 131 to the light emission number setting unit 141. The environment monitoring device 150 may be, for example, a light measuring device such as an optical spectrum analyzer or an optical power meter. For example, when the environment monitoring device 150 measures the amount of light around the ranging device, the light emission number setting unit 141 calculates noise from the amount of light and updates information on noise used to acquire the light emission number. Then, the light emission number setting unit 141 calculates the light emission number for ensuring a predetermined SNR using the updated noise. This calculation may be performed at any time or may be performed at a predetermined timing. By arranging the environment monitoring device 150, the light emission number setting unit 141 can adjust the light emission number according to the noise environment of the ranging device. Therefore, even when the noise environment changes, it is possible to secure a predetermined SNR, and the distance measurement accuracy is stabilized.

Note that it is not essential to arrange the environment monitoring device 150, and the processing may be performed without updating the amount of noise light. In this case, the device configuration may be simplified.

Although FIG. 2 illustrates an example in which the ranging device includes four parts that are the light source device 120, the light detection device 130, the arithmetic processing device 140, and the environment monitoring device 150, the configuration of the ranging device is not limited thereto. The combination of the constituent elements of the ranging device can be appropriately changed.

As described above, when two or more photons are incident on the light detection unit 131 in a period of one time window, a discrepancy occurs between the number of incident photons and the number of photons detections (the number of incident events). Since the square root of two, in one embodiment, which is the number of photons, is approximately 1.4, the SNR of the ranging device is 1.4 or less. In general, detection accuracy (accumulated probability) can be calculated from SNR, and detection accuracy of 50% or more in order to detect a photon with a probability equal to or higher than noise. In one embodiment, at least from the viewpoint of obtaining this detection accuracy, the SNR of the ranging device is 0.7 or more. As described above, in another embodiment, the SNR of the ranging device is set in the range of 0.7 to 1.4.

There is a trade-off relationship in which the larger the time constant, the larger the SNR, but the lower the responsiveness. In general, regarding transient responses, the SNR at which both signal quality and responsiveness are achieved to some extent is a value slightly greater than one. Therefore, in one embodiment, the SNR of the ranging device is set in the range of 1.0 to 1.2.

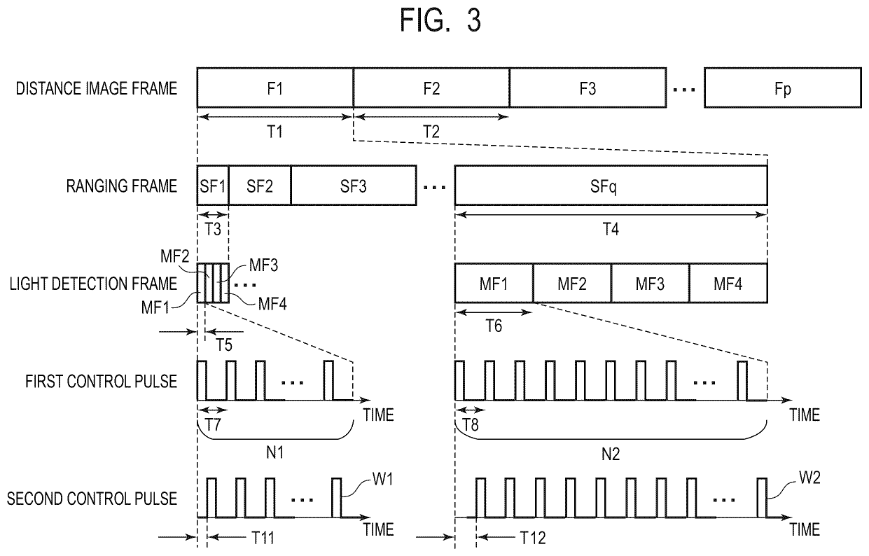

FIG. 3 is a diagram schematically illustrating an outline of an operation of the ranging device according to the present embodiment. FIG. 3 schematically illustrates acquisition periods of the distance image frame, the ranging frame, and the light detection frame by arranging blocks in the horizontal direction. The horizontal direction in FIG. 3 indicates the passage of time, and one block indicates an acquisition period of one distance image frame, one ranging frame, and one light detection frame. FIG. 3 schematically illustrates timings of the first control pulse and the second control pulse.

Distance image frames F1 to Fp in FIG. 3 indicate generation periods of the distance image frames generated by the distance image calculation unit 143. For example, the distance image frame F1 is generated during a period T1, and the distance image frame F2 is generated during a period T2. The length of the period T1 and the length of the period T2 may be the same or different. Here, p is the number of distance image frames.

Ranging frames SF1 to SFq in FIG. 3 indicate generation periods of the ranging frames generated by the ranging frame output unit 137. For example, the ranging frame SF1 is generated in a period T3, and the ranging frame SFq is generated in a period T4. Here, q is the number of ranging frames. The number of ranging frames is set by the distance image calculation unit 143 and is supplied to the light emission number setting unit 141. The ranging frames SF1 to SFq are used to generate one distance image frame F1. The ranging frames SF1 to SFq include information indicating the number of incident events of photons at different measurement distances.

Light detection frames MF1 to MF4 in FIG. 3 indicate generation periods of the light detection frames generated by the light detection frame readout unit 135. The light detection frames MF1 to MF4 are used to generate one of the ranging frames SF1 to SFq. For example, the light detection frame MF1 used to generate the ranging frame SF1 is generated in a period T5. For example, the light detection frame MF1 used to generate the ranging frame SFq is generated in a period T6. In the example of FIG. 3, the light detection frame addition unit 136 adds four light detection frames to generate one ranging frame. Since the gradation of each light detection frame is one bit, the gradation of the ranging frame is two bits.

The “first control pulse” and the “second control pulse” in FIG. 3 indicate the patterns of the control signals output from the gate pulse control unit 132. The first control pulse is a signal for controlling the light emission timing of the pulsed light source 121, and the second control pulse is a signal for controlling the timing of the time window for detecting light. The gate pulse control unit 132 outputs a first control pulse to the light source control unit 122, and the light source control unit 122 controls the pulsed light source 121 based on the first control pulse. The pulsed light source 121 repeatedly emits light in the pattern of the first control pulse illustrated in FIG. 3. The gate pulse control unit 132 outputs the second control pulse to the light detection unit 131, and the light detection unit 131 repeatedly receives light during the first time window W1 and the second time window W2 of the second control pulse illustrated in FIG. 3. The time difference between the first control pulse and the second control pulse corresponds to the measurement distance. In the measurement (first measurement) of the light detection frame MF1 (first light detection frame) for generating the ranging frame SF1, the time difference T11 between the first control pulse and the second control pulse corresponds to the measurement distance (first distance) of the ranging frame SF1. In the measurement (second measurement) of the light detection frame MF1 (second light detection frame) for generating the ranging frame SFq, the time difference T12 between the first control pulse and the second control pulse corresponds to the measurement distance (second distance) of the ranging frame SFq.

FIG. 3 illustrates the first control pulse and the second control pulse in the period T5 and the first control pulse and the second control pulse in the period T6. The number of pulses in the first control pulse corresponds to the light emission number. The light emission number is set by the light emission number setting unit 141.

As illustrated in FIG. 3, in the present embodiment, the first light emission number N1 of the laser pulsed light (first pulsed light) in the period T5 and the second light emission number N2 of the laser pulsed light (second pulsed light) in the period T6 are different from each other. In the example of FIG. 3, the second light emission number N2 is greater than the first light emission number N1, and a length of a time interval T7 of the first control pulse in the period T5 and a length of a time interval T8 of the first control pulse in the period T6 are the same. In this case, the length of the period T6 is set longer than that of the period T5. The time interval T7 and the time interval T8 may be different from each other.

The length of the period T5 of the light detection frame may be appropriately adjusted so that pulses of the first light emission number N1 are included, and the length of the period T6 of the light detection frame may be appropriately adjusted so that pulses of the second light emission number N2 are included. For example, the length of the period T5 of the light detection frame may be minimum length such that the pulses of the first light emission number N1 are included, and the length of the period T6 of the light detection frame may be minimum length such that the pulses of the second light emission number N2 are included. In the example of FIG. 3, since the second light emission number N2 is greater than the first light emission number N1, the period T6 is set to be longer than the period T5. In this way, by adjusting the length of the period of the light detection frame according to the light emission number, it is possible to improve the frame rate of the signal output from the ranging device, and it is possible to reduce the ghost (afterimage) of the object 191 that may be included in the distance image.

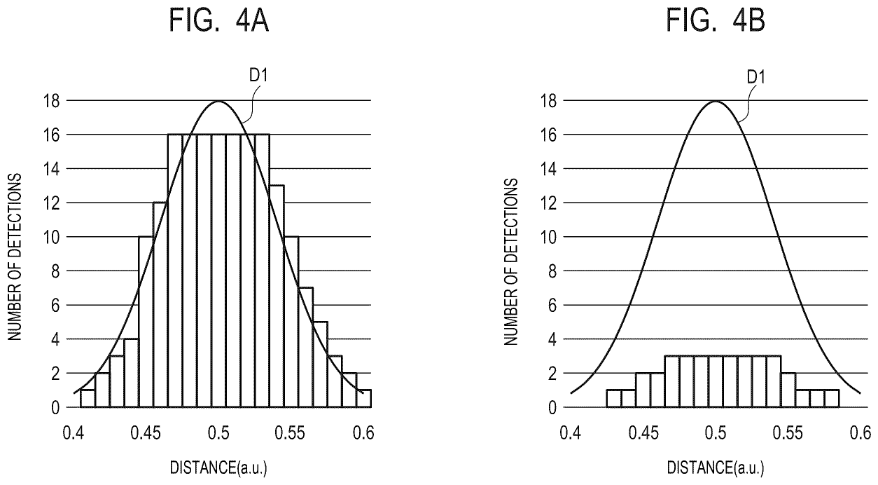

FIGS. 4A and 4B are graphs illustrating the effect of adjusting the light emission number. FIG. 4A is an example of a frequency distribution in a case where the light emission number of the laser pulsed light in the light detection frame is adjusted according to the distance as described above. FIG. 4B is an example of the frequency distribution when the light emission number of the laser pulsed light in the light detection frame is fixed with respect to the distance. The horizontal axis of FIGS. 4A and 4B indicates the measurement distance in arbitrary units, and the vertical axis of FIGS. 4A and 4B indicates the number of detections of the incident event of the photon. The number of intervals on the horizontal axis corresponds to the number of ranging frames, and the number of detections on the vertical axis corresponds to the pixel value of the ranging frame. The intensity distribution D1 illustrated in FIGS. 4A and 4B schematically indicates the distribution of the intensity of the reflected light from the object 191. When the measurement is performed ideally, the number of detections approximates the intensity distribution D1.

As illustrated in FIG. 4B, when the light emission number of the laser pulsed light is fixed with respect to the distance, the number of detections close to the intensity distribution D1 may not be obtained. The number of photons incident on the light detection unit 131 within the period of the time window depends on the distance. As described with reference to FIG. 1B, as the measurement distance is shorter, the number of photons incident on the light detection unit 131 within the period of the time window is larger, and thus the SNR of the ranging device changes depending on the measurement distance. A light detection frame constituted by 1-bit information is a signal indicating the presence or absence of an incident event of a photon. Therefore, the determination results are not different between a case where one photon is incident on the light detection unit 131 within a period of one time window and a case where a plurality of photons are incident on the light detection unit 131 within a period of one time window. That is, when the SNR of the ranging device is too high, the signal is saturated, and a discrepancy occurs between the number of photons actually incident and the number of detections of the incident event. Therefore, as illustrated in FIG. 4B, a frequency distribution in which a peak is unclear may be obtained.

On the other hand, as in the present embodiment, by appropriately changing the number of photons incident on the light detection unit 131 within the period of the time window in accordance with the measurement distance by adjusting the light emission number, the discrepancy between the number of photons actually incident and the number of detections of the incident event can be reduced. In this case, the discrepancy between the number of photons incident in the time window and the number of incident events is suppressed, and a frequency distribution with a clear peak is obtained as illustrated in FIG. 4A. Therefore, the ranging may be stabilized.

The above-described effect becomes more pronounced in the ranging at relatively short distance (for example, 10 m or less). This is because, as illustrated in FIG. 1i, the shorter the distance measurement, the greater the dependency of the intensity of light on the distance.

The intensity of the reflected pulsed light from the object 191 also depends on the reflectance of the object 191. Therefore, in the present embodiment, since the influence of the dependency of the number of incident photons on the measurement distance can be reduced, the reflectance between the plurality of objects 191 can be compared from the number of detections of the incident event.

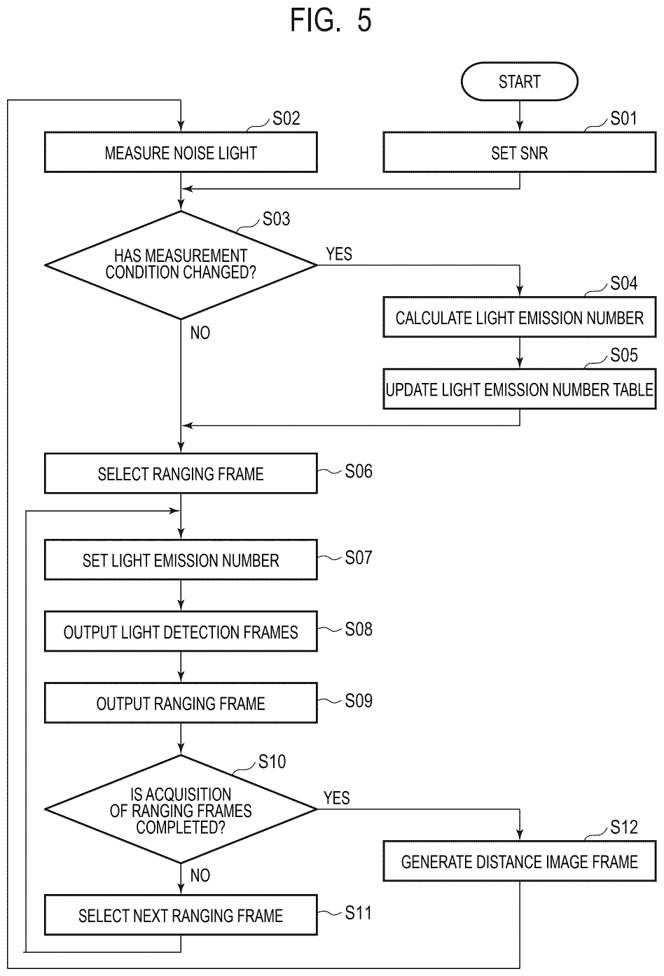

Next, an example of a ranging procedure in the present embodiment will be described with reference to FIG. 5. FIG. 5 is a flowchart illustrating an operation of the ranging device according to the present embodiment. Description overlapping with the above description may be omitted or simplified.

In step S01 after the distance measurement is started, the light emission number setting unit 141 sets the SNR to be used for the calculation of the light emission number by reading a set value of the SNR that is set in advance. Thereafter, the process proceeds to step S03.

Although the SNR generated in the step S01 is used in the first generation of the distance image frame after the start of the distance measurement, the setting of the SNR may be updated in the second and subsequent generation of the distance image frames. In step S02, the environment monitoring device 150 measures noise light. The noise light may be, for example, sunlight. The environment monitoring device 150 outputs the measurement result of the noise light to the light emission number setting unit 141. Thereafter, the process proceeds to step S03.

In the step S03, the light emission number setting unit 141 determines whether or not the measurement condition has changed based on the measurement result of the noise light. This determination may be based on, for example, a temporal change in the amount of noise light. When it is determined that the measurement condition has changed, the process proceeds to step S04 (YES in the step S03). When it is determined that the measurement condition has not changed, the process proceeds to step S06 (NO in the step S03). In the first generation of the distance image frame, the same determination as in the case where the measurement condition has changed is performed. That is, the process proceeds to the step S04 (YES in the step S03).

In the step S04, the light emission number setting unit 141 calculates the light emission number (the first light emission number N1 and the second light emission number N2 in FIG. 3) in acquisition of one light detection frame for each ranging frame. In the second and subsequent generation of the distance image frames, the measurement result of the noise light may be used for this calculation. Thereafter, in step S05, the light emission number table is updated based on the calculated light emission number, and the process proceeds to the step S06. Although FIG. 5 illustrates an operation example in which the light emission number setting unit 141 sets the light emission number with reference to the light emission number table, the light emission number setting unit 141 may calculate and set the light emission number using a formula. In this case, the processing of the step S05 may be replaced with the update of a parameter of the formula.

Note that the light emission number setting unit 141 may hold an initial value of the light emission number that is set in advance, and in this case, the step S04 and the step S05 may be omitted when the distance image frame is generated for the first time.

In the step S06, the light detection frame setting unit 134 selects a ranging frame to be measured. The ranging frame selected here is one of the ranging frames SF1 to SFq in the example of FIG. 3. Thereafter, in step S07, the light detection frame setting unit 134 reads the light emission number (the first light emission number N1 or the second light emission number N2) to be used for measurement of the light detection frame for generation of the selected ranging frame with reference to the light emission number table. Then, the light detection frame setting unit 134 outputs information on the light emission number to the gate pulse control unit 132.

In step 508, the light detection frame readout unit 135 sequentially reads out the light detection frames MF1 to MF4 for generation of the selected ranging frame, and outputs them to the light detection frame addition unit 136. The light detection frame addition unit 136 adds the light detection frames MF1 to MF4.

In step 509, the ranging frame output unit 137 outputs the ranging frame generated based on the light detection frames MF1 to MF4 to the ranging frame group storage unit 142. The ranging frame group storage unit 142 stores the acquired ranging frame.

In step S10, the light detection frame setting unit 134 determines whether acquisition of a predetermined number of ranging frames is completed. In the example of FIG. 3, the light detection frame setting unit 134 determines whether the acquisition of the last ranging frame SFq is completed. When it is determined that the acquisition of the predetermined number of ranging frames is not completed (NO in the step S10), the process proceeds to step S11. In the step S11, the light detection frame setting unit 134 selects a ranging frame to be measured next. The ranging frame selected here is a ranging frame next to the last measured ranging frame, and in the example of FIG. 3, is one of the ranging frames SF2 to SFq. Thereafter, the process proceeds to the step S07, and the next ranging frame is measured.

When it is determined in the step S10 that the acquisition of the predetermined number of ranging frames is completed (YES in the step S10), the process proceeds to step S12. In the step S12, the distance image calculation unit 143 generates a distance image frame. Thereafter, the process proceeds to the step S02, where the noise light is measured and the next distance image frame is acquired.

As described above, according to the present embodiment, the light emission number can be adjusted according to the distance to be measured. Therefore, a photoelectric conversion device and a method of controlling the photoelectric conversion device capable of reducing power consumption are provided.

When the ranging device does not include the environment monitoring device 150, the processing of steps S02 to S05 may be omitted. As described above, a part of the processing of FIG. 5 may be omitted, or another processing may be added to the processing of FIG. 5.

Hereinafter, a calculation example of the light emission number according to the first embodiment will be described. In addition, in the present calculation example, the configuration and the measurement conditions of the ranging device which are premises of the calculation are described in detail, but the configuration and the measurement conditions applicable to the ranging device of the present embodiment are not limited thereto.

First, a description will be given of the configuration and the measurement conditions of the ranging device which are premises of the calculation. The wavelength of the laser pulsed light emitted from the light source device 120 is 940 nm, and the irradiation angle of the laser pulsed light is 20 degrees. The time intervals T7 and T8 of the first control pulse in FIG. 3 are both 1000 ns. The time intervals of the first time window W1 and the second time window W2 of the second control pulse are also 1000 ns. The laser pulsed light output from the light source device 120 is irradiated to the object 191 through a diffusion plate having a diffusion angle of 80 degrees. The average output of the light source device 120 is about 0.18 W. This condition corresponds to class one of the laser safety standard, and the light source device 120 satisfies the eye-safe condition.

A SPAD of one million pixels is used for the light detection unit 131 of the light detection device 130. The light receiving area of the light detection unit 131 is about 5 mm×5 mm, and the detection efficiency, which is the photon detection efficiency (PDE), of the light detection unit 131 is 24%. The optical system of the light detection unit 131 includes a bandpass filter having a bandwidth of 10 nm and an imaging lens having an angle of view of 23 degrees.

The time widths of the first time window W1 and the second time window W2 of the second control pulse (the length of one period in which photons are detected) are both 0.2 ns. The distance image frame includes 16 ranging frames. The measurable range of the ranging device is 0.15 m to 3 m, and this measurable range is divided into 16 measurement distances by 16 ranging frames. The ranging frame includes 16 light detection frames. Accordingly, the gradation of the ranging frame is four bits.

The SNR used by the light emission number setting unit 141 to calculate the light emission number is 1.1. It is assumed that the reflectance of the object 191 is 10%, the illuminance of the noise light is 1000 lux, and the object 191 is located indoors.

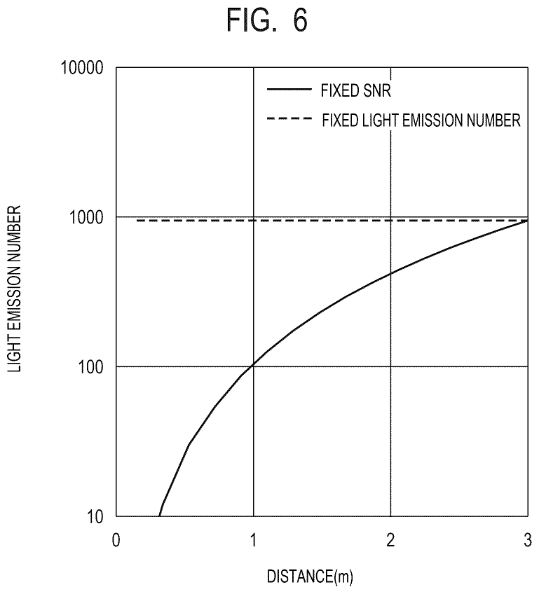

FIG. 6 is a graph illustrating an example of calculation of the light emission number according to the present embodiment. The horizontal axis of FIG. 6 indicates the distance from the ranging device to the object 191, and the vertical axis of FIG. 6 indicates the light emission number used to detect photons in each time window on a logarithmic scale. The solid line in FIG. 6 is an example of the light emission number calculated so that the SNR is fixed with respect to the distance. The broken line in FIG. 6 is a calculation example of the light emission number when the light emission number is 1000, that is, when the light emission number is fixed with respect to the distance. The ranging device detects incident events of photons using the light emission number calculated in this manner, and outputs light detection frames, the number of the light detection frames corresponding to the light emission number. As illustrated in FIG. 6, when the SNR is fixed, the number of photons incident during the time window varies inversely in proportion to the square of the distance. Therefore, the shorter the distance from the ranging device is, the smaller the calculated light emission number is.

The total of the light emission number used to generate the distance image frame corresponds to the integral value of the light emission number. Therefore, it is understood that the light emission number is smaller in the example in which the SNR is fixed than in the example in which the light emission number is fixed, according to the integrated value of the graph illustrated in FIG. 6.

For example, when the ranging device is operated by applying the above-described conditions, the frame rate of the distance image frame is about 4 fps in an example in which the light emission number is fixed. In contrast, in an example in which the SNR is fixed, the frame rate of the distance image frame is about 11 fps. Therefore, by setting the light emission number so as to fix the SNR, the frame rate can be improved.

In this manner, by changing the light emission number according to the measurement distance and adjusting the length of the measurement period of the ranging frame according to the light emission number, it is possible to achieve both improvement of the frame rate of the distance image frame and power saving of the ranging device.

Although FIG. 6 illustrates an embodiment in which the light emission number increases as the distance increases, the relationship between the distance and the light emission number is not limited thereto. For example, the light emission number may have a maximum value with respect to the distance. In this case, the light emission number decreases at a distance longer than the distance corresponding to the maximum value. By setting the light emission number in this manner, it is possible to perform an operation of intentionally lowering the detection accuracy of the incident event of the photons for the measurement distance exceeding the desired range of the ranging. As a result, for example, a distance image frame in which unnecessary distance information of the background is hidden can be acquired, and the recognition performance of the object 191 can be improved. Further, by reducing the light emission number at the long distance, power consumption of the ranging device can be reduced. Therefore, both the power saving of the ranging device and the recognition performance of the object 191 can be achieved.

### Second Embodiment

In the present embodiment, a modified example of the ranging operation of the ranging device of the first embodiment will be described. In the present embodiment, description of elements common to those of the first embodiment may be omitted or simplified.

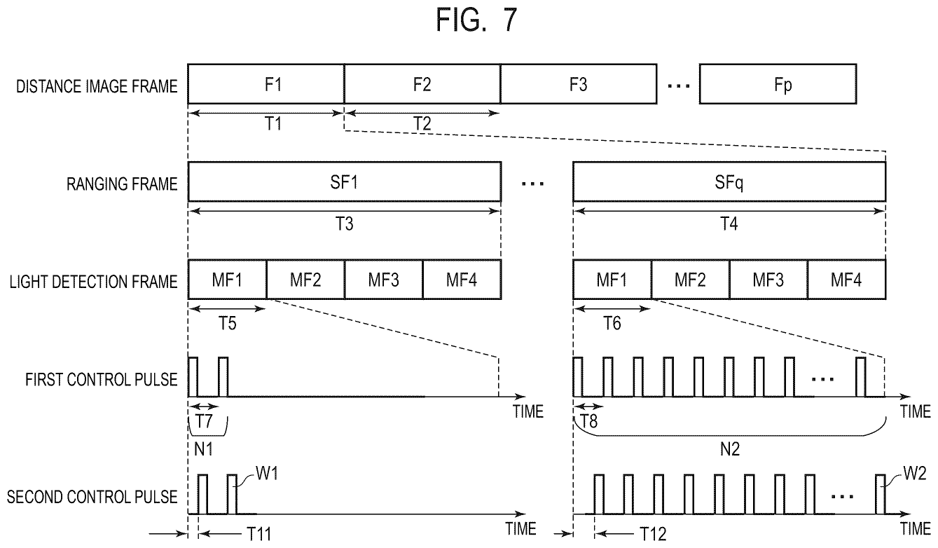

FIG. 7 is a diagram schematically illustrating the outline of the operation of the ranging device according to the present embodiment. FIG. 3 of the first embodiment illustrates an example in which the lengths of the periods T5 and T6 of the light detection frame are appropriately adjusted in accordance with the first light emission number N1 and the second light emission number N2. That is, as illustrated in FIG. 3, in the example of the first embodiment, the length of the period T5 and the length of the period T6 are different from each other. In contrast, in the present embodiment, as illustrated in FIG. 7, the length of the period T5 and the length of the period T6 are the same regardless of the first light emission number N1 and the second light emission number N2. As exemplified in the measurement of the light detection frame MF1 of the ranging frame SF1 in FIG. 7, by waiting for the light emission operation until the period T5 ends after the light emissions of the number of times of the first light emission number N1 ends, the length of the period T5 can be set to a constant length regardless of the light emission number.

According to the configuration of the present embodiment, as in the first embodiment, a photoelectric conversion device and a method of controlling a photoelectric conversion device capable of reducing power consumption are provided. Further, in the configuration of the present embodiment, since a blanking period in which the pulsed light is not emitted occurs, the average output of the laser pulsed light emitted from the light source device 120 is reduced. Therefore, the light source device 120 can easily satisfy the eye-safe condition of the laser safety standard, and the safety of the ranging device can be further improved.

### Third Embodiment

In the present embodiment, a modification of the method of calculating the light emission number of the ranging device according to the first embodiment will be described. In the present embodiment, description of elements common to those of the first embodiment may be omitted or simplified.

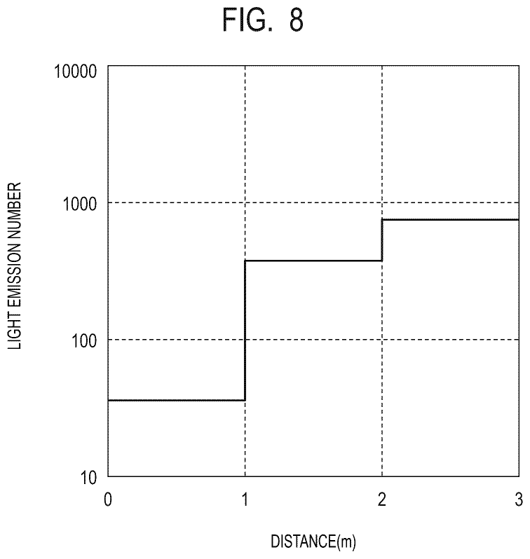

FIG. 8 is a graph illustrating an example of calculation of the light emission number in the present embodiment. In FIG. 6 of the first embodiment, the light emission number is calculated so that the light emission number is continuously set with respect to the ranging distance. On the other hand, in the present embodiment, the calculation of the light emission number is performed by being divided into a plurality of distance regions. That is, the light emission number in each distance region is constant regardless of the distance, and the light emission number is set so as to change stepwise with respect to the distance when a plurality of distance regions are viewed. For example, in the example of FIG. 8, the light emission number setting unit 141 calculates the light emission number for three distance regions including a first region less than 1 m, a second region from 1 m to 2 m, and a third region from 2 m to 3 m. Then, a certain light emission number is allocated in each region. Note that, the number of divisions of the distance region is not limited to three.

According to the configuration of the present embodiment, as in the first embodiment, a photoelectric conversion device and a method of controlling a photoelectric conversion device capable of reducing power consumption are provided. Further, in the calculation method of the light emission number according to the present embodiment, the type of the value of the light emission number is limited to the number of distance regions. Therefore, as compared with the case where the light emission number is continuously set with respect to the ranging distance, the calculation resource of the light emission number setting unit 141 is reduced, and thus the operation of the ranging device can be speeded up.

### Fourth Embodiment

In the present embodiment, a modification of the device configuration of the ranging device according to the first embodiment will be described. In the present embodiment, description of elements common to those of the first embodiment may be omitted or simplified.

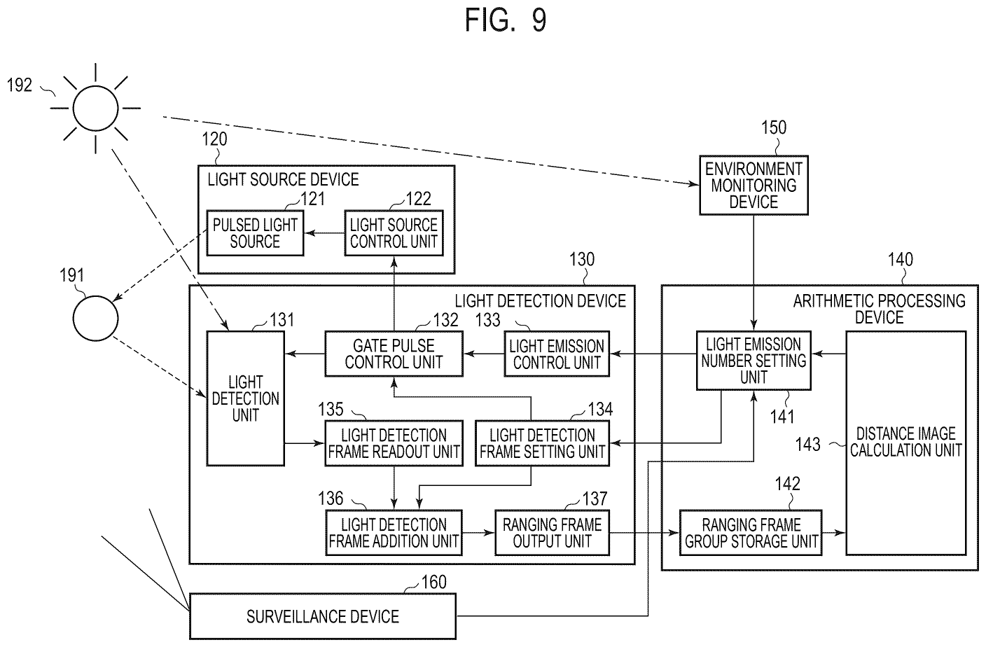

FIG. 9 is a diagram schematically illustrating the outline of the operation of the ranging device according to the present embodiment. The ranging device of the present embodiment further includes a surveillance device 160 in addition to the configuration of the ranging device of the first embodiment illustrated in FIG. 2. The surveillance device 160 is, for example, a radar device or an imaging device. Examples of the imaging device include a visible light camera and an infrared camera. The surveillance device 160 surveilles a predetermined surveillance range and surveilles the position, movement, and the like of the object 191 present within the surveillance range. The ranging device performs control to switch an operation state of the ranging device based on the surveillance result.

A specific example of the control performed based on the surveillance result will be described. For example, the distance image calculation unit 143 may detect an approximate position of the object 191 based on the surveillance result to adjust the ranging range of the distance image frame so as to include the detected position. In addition, the light emission number setting unit 141 may detect an approximate position of the object 191 based on the surveillance result to perform weighting on the light emission number based on the detected position. In this case, the light emission number may be reduced for a distance at which there is a low possibility that the object 191 exists, or the light emission number may be increased for a distance at which there is a high possibility that the object 191 exists.

Further, the ranging device may detect a state of an object present within a ranging angle of view of the ranging device based on the surveillance result to switch on or off an operation state of the ranging device according to the detected state. When the surveillance device 160 is an imaging device, the surveillance device 160 may detect whether the noise source 192 (for example, a light emitting body) is present. When the noise source 192 is detected, the ranging device may stop the ranging operation for the vicinity of the noise source 192. In other words, the ranging device may specify the range in which the ranging operation is performed from the ranging angle of view of the ranging device based on the surveillance result, and may select the pixel in which the ranging operation is performed from the pixels constituting the light detection unit 131.

According to the configuration of the present embodiment, as in the first embodiment, a photoelectric conversion device and a method of controlling a photoelectric conversion device capable of reducing power consumption are provided. Further, in the present embodiment, unnecessary operations can be reduced based on the surveillance result of the surveillance device 160. Therefore, power consumption can be further reduced.

### Fifth Embodiment

In the present embodiment, a specific configuration example of a photoelectric conversion device including an avalanche photodiode, which can be applied to the light detection unit 131 of the ranging device according to the first to fourth embodiments, will be described. The configuration example of the present embodiment is an example, and the photoelectric conversion device applicable to the light detection unit 131 is not limited thereto.

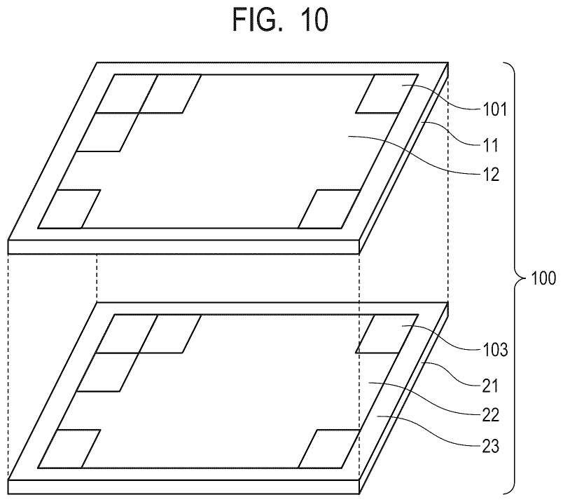

FIG. 10 is a schematic diagram illustrating an overall configuration of the photoelectric conversion device 100 according to the present embodiment. The photoelectric conversion device 100 includes a sensor substrate 11 (first substrate) and a circuit substrate 21 (second substrate) stacked on each other. The sensor substrate 11 and the circuit substrate 21 are electrically connected to each other. The sensor substrate 11 has a pixel region 12 in which a plurality of pixels 101 are arranged to form a plurality of rows and a plurality of columns. The circuit substrate 21 includes a first circuit region 22 in which a plurality of pixel signal processing units 103 are arranged to form a plurality of rows and a plurality of columns, and a second circuit region 23 arranged outside the first circuit region 22. The second circuit region 23 may include a circuit for controlling the plurality of pixel signal processing units 103. The sensor substrate 11 has a light incident surface for receiving incident light and a connection surface opposed to the light incident surface. The sensor substrate 11 is connected to the circuit substrate 21 on the connection surface side. That is, the photoelectric conversion device 100 is a so-called backside illumination type.

In this specification, the term “plan view” refers to a view from a direction perpendicular to a surface opposite to the light incident surface. The cross section indicates a surface in a direction perpendicular to a surface opposite to the light incident surface of the sensor substrate 11. Although the light incident surface may be a rough surface when viewed microscopically, in this case, a plan view is defined with reference to the light incident surface when viewed macroscopically.

In the following description, the sensor substrate 11 and the circuit substrate 21 are diced chips, but the sensor substrate 11 and the circuit substrate 21 are not limited to chips. For example, the sensor substrate 11 and the circuit substrate 21 may be wafers. When the sensor substrate 11 and the circuit substrate 21 are diced chips, the photoelectric conversion device 100 may be manufactured by being diced after being stacked in a wafer state, or may be manufactured by being stacked after being diced.

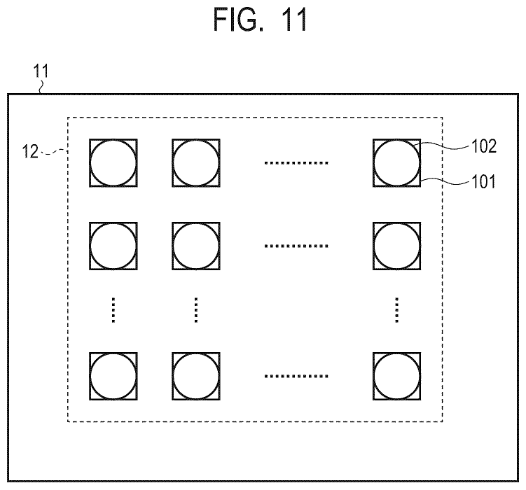

FIG. 11 is a schematic block diagram illustrating an arrangement example of the sensor substrate 11. In the pixel region 12, a plurality of pixels 101 are arranged to form a plurality of rows and a plurality of columns. Each of the plurality of pixels 101 includes a photoelectric conversion unit 102 including an avalanche photodiode (hereinafter referred to as APD) as a photoelectric conversion element in the substrate.

Of the charge pairs generated in the APD, the conductivity type corresponding to the charge used as the signal charge is referred to as a first conductivity type. The first conductivity type refers to a conductivity type in which a charge having the same polarity as the signal charge is a majority carrier. Further, a conductivity type opposite to the first conductivity type, that is, a conductivity type in which a majority carrier is a charge having a polarity different from that of a signal charge is referred to as a second conductivity type. In the APD described below, the anode of the APD is set to a fixed potential, and a signal is extracted from the cathode of the APD. Accordingly, the semiconductor region of the first conductivity type is an N-type semiconductor region, and the semiconductor region of the second conductivity type is a P-type semiconductor region. Note that the cathode of the APD may have a fixed potential and a signal may be extracted from the anode of the APD. In this case, the semiconductor region of the first conductivity type is the P-type semiconductor region, and the semiconductor region of the second conductivity type is then N-type semiconductor region. Although the case where one node of the APD is set to a fixed potential is described below, potentials of both nodes may be varied.

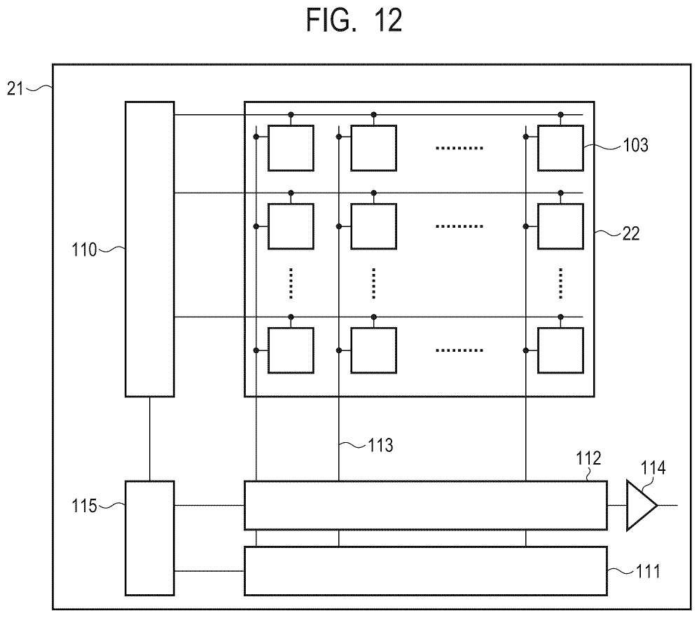

FIG. 12 is a schematic block diagram illustrating a configuration example of the circuit substrate 21. The circuit substrate 21 has the first circuit region 22 in which a plurality of pixel signal processing units 103 are arranged to form a plurality of rows and a plurality of columns.

The circuit substrate 21 includes a vertical scanning circuit 110, a horizontal scanning circuit 111, a reading circuit 112, a pixel output signal line 113, an output circuit 114, and a control signal generation unit 115. The plurality of photoelectric conversion units 102 illustrated in FIG. 11 and the plurality of pixel signal processing units 103 illustrated in FIG. 12 are electrically connected to each other via connection wirings provided for each pixel 101.

The control signal generation unit 115 is a control circuit that generates control signals for driving the vertical scanning circuit 110, the horizontal scanning circuit 111, and the reading circuit 112, and supplies the control signals to these units. As a result, the control signal generation unit 115 controls the driving timings and the like of each unit.

The vertical scanning circuit 110 supplies control signals to each of the plurality of pixel signal processing units 103 based on the control signal supplied from the control signal generation unit 115. The vertical scanning circuit 110 supplies control signals for each row to the pixel signal processing unit 103 via a driving line provided for each row of the first circuit region 22. As will be described later, a plurality of driving lines may be provided for each row. A logic circuit such as a shift register or an address decoder can be used for the vertical scanning circuit 110. Thus, the vertical scanning circuit 110 selects a row to be output a signal from the pixel signal processing unit 103.

The signal output from the photoelectric conversion unit 102 of the pixel 101 is processed by the pixel signal processing unit 103. The pixel signal processing unit 103 counts the number of pulses output from the APD included in the photoelectric conversion unit 102 to acquire and hold a digital signal.

It is not always necessary to provide one pixel signal processing unit 103 for each of the pixels 101. For example, one pixel signal processing unit 103 may be shared by a plurality of pixels 101. In this case, the pixel signal processing unit 103 sequentially processes the signals output from the photoelectric conversion units 102, thereby providing the function of signal processing to each pixel 101.

The horizontal scanning circuit 111 supplies control signals to the reading circuit 112 based on a control signal supplied from the control signal generation unit 115. The pixel signal processing unit 103 is connected to the reading circuit 112 via a pixel output signal line 113 provided for each column of the first circuit region 22. The pixel output signal line 113 in one column is shared by a plurality of pixel signal processing units 103 in the corresponding column. The pixel output signal line 113 includes a plurality of wirings, and has at least a function of outputting a digital signal from the pixel signal processing unit 103 to the reading circuit 112, and a function of supplying a control signal for selecting a column for outputting a signal to the pixel signal processing unit 103. The reading circuit 112 outputs a signal to an external storage unit or signal processing unit of the photoelectric conversion device 100 via the output circuit 114 based on the control signal supplied from the control signal generation unit 115.

The arrangement of the photoelectric conversion units 102 in the pixel region 12 may be one-dimensional. Further, the function of the pixel signal processing unit 103 does not necessarily have to be provided one by one in all the pixels 101. For example, one pixel signal processing unit 103 may be shared by a plurality of pixels 101. In this case, the pixel signal processing unit 103 sequentially processes the signals output from the photoelectric conversion units 102, thereby providing the function of signal processing to each pixel 101.

As illustrated in FIGS. 11 and 12, the first circuit region 22 having a plurality of pixel signal processing units 103 is arranged in a region overlapping the pixel region 12 in the plan view. In the plan view, the vertical scanning circuit 110, the horizontal scanning circuit 111, the reading circuit 112, the output circuit 114, and the control signal generation unit 115 are arranged so as to overlap a region between an edge of the sensor substrate 11 and an edge of the pixel region 12. In other words, the sensor substrate 11 includes the pixel region 12 and a non-pixel region arranged around the pixel region 12. In the circuit substrate 21, the second circuit region 23 (described above in FIG. 10) having the vertical scanning circuit 110, the horizontal scanning circuit 111, the reading circuit 112, the output circuit 114, and the control signal generation unit 115 is arranged in a region overlapping with the non-pixel region in the plan view.

Note that the arrangement of the pixel output signal line 113, the arrangement of the reading circuit 112, and the arrangement of the output circuit 114 are not limited to those illustrated in FIG. 12. For example, the pixel output signal lines 113 may extend in the row direction, and may be shared by a plurality of pixel signal processing units 103 in corresponding rows. The reading circuit 112 may be provided so as to be connected to the pixel output signal line 113 of each row.

FIG. 13 is a schematic block diagram illustrating a configuration example of one pixel of the photoelectric conversion unit 102 and the pixel signal processing unit 103 according to the present embodiment. FIG. 13 schematically illustrates a more specific configuration example including a connection relationship between the photoelectric conversion unit 102 arranged in the sensor substrate 11 and the pixel signal processing unit 103 arranged in the circuit substrate 21. In FIG. 13, driving lines between the vertical scanning circuit 110 and the pixel signal processing unit 103 in FIG. 12 are illustrated as driving lines 213, 214, and 215.

The photoelectric conversion unit 102 includes an APD 201. The pixel signal processing unit 103 includes a quenching element 202, a waveform shaping unit 210, a counter circuit 211, a selection circuit 212, and a gating circuit 216. The pixel signal processing unit 103 may include at least one of the waveform shaping unit 210, the counter circuit 211, the selection circuit 212, and the gating circuit 216.

The APD 201 generates a charge corresponding to incident light by photoelectric conversion. A voltage VL (first voltage) is supplied to the anode of the APD 201. The cathode of the APD 201 is connected to a first terminal of the quenching element 202 and an input terminal of the waveform shaping unit 210. A voltage VH (second voltage) higher than the voltage VL supplied to the anode is supplied to the cathode of the APD 201. As a result, a reverse bias voltage that causes the APD 201 to perform the avalanche multiplication operation is supplied to the anode and the cathode of the APD 201. In the APD 201 to which the reverse bias voltage is supplied, when a charge is generated by the incident light, this charge causes avalanche multiplication, and an avalanche current is generated.

The operation modes in the case where a reverse bias voltage is supplied to the APD 201 include a Geiger mode and a linear mode. The Geiger mode is a mode in which a potential difference between the anode and the cathode is higher than a breakdown voltage, and the linear mode is a mode in which a potential difference between the anode and the cathode is near or lower than the breakdown voltage.

The APD operated in the Geiger mode is referred to as a single photon avalanche diode (SPAD). In this case, for example, the voltage VL (first voltage) is −30 V, and the voltage VH (second voltage) is 1 V. The APD 201 may operate in the linear mode or the Geiger mode. In the case of the SPAD, a potential difference becomes greater than that of the APD of the linear mode, and the effect of avalanche multiplication becomes significant, so that the SPAD is used.

The quenching element 202 functions as a load circuit (quenching circuit) when a signal is multiplied by avalanche multiplication. The quenching element 202 suppresses the voltage supplied to the APD 201 and suppresses the avalanche multiplication (quenching operation). Further, the quenching element 202 returns the voltage supplied to the APD 201 to the voltage VH by passing a current corresponding to the voltage drop due to the quenching operation (recharge operation). The quenching element 202 may be, for example, a resistive element.

The waveform shaping unit 210 shapes the potential change of the cathode of the APD 201 obtained at the time of photon detection, and outputs a pulse signal. For example, an inverter circuit is used as the waveform shaping unit 210. Although FIG. 13 illustrates an example in which one inverter is used as the waveform shaping unit 210, the waveform shaping unit 210 may be a circuit in which a plurality of inverters are connected in series, or may be another circuit having a waveform shaping effect.

The gating circuit 216 performs gating such that the pulse signal output from the waveform shaping unit 210 passes through for a predetermined period. During a period in which the pulse signal can pass through the gating circuit 216, a photon incident on the APD 201 is counted by the counter circuit 211 in the subsequent stage. Accordingly, the gating circuit 216 controls an exposure period during which a signal based on incident light is generated in the pixel 101. The period during which the pulse signal passes is controlled by a control signal supplied from the vertical scanning circuit 110 through the driving line 215. FIG. 13 illustrates an example in which one AND circuit is used as the gating circuit 216. The pulse signal and the control signal are input to two input terminals of the AND circuit. The AND circuit outputs logical conjunction of these to the counter circuit 211. Note that, the gating circuit 216 may have a circuit configuration other than the AND circuit as long as it realizes gating. Also, the waveform shaping unit 210 and the gating circuit 216 may be integrated by using a logic circuit such as a NAND circuit.

The counter circuit 211 counts the pulse signals output from the waveform shaping unit 210 via the gating circuit 216, and holds a digital signal indicating the count value. When a control signal is supplied from the vertical scanning circuit 110 through the driving line 213, the counter circuit 211 resets the held signal.

The selection circuit 212 is supplied with a control signal from the vertical scanning circuit 110 illustrated in FIG. 12 through the driving line 214 illustrated in FIG. 13. In response to this control signal, the selection circuit 212 switches between the electrical connection and the non-connection of the counter circuit 211 and the pixel output signal line 113. The selection circuit 212 includes, for example, a buffer circuit or the like for outputting a signal corresponding to a value held in the counter circuit 211.

In the example of FIG. 13, the selection circuit 212 switches between the electrical connection and the non-connection of the counter circuit 211 and the pixel output signal line 113; however, the method of controlling the signal output to the pixel output signal line 113 is not limited thereto. For example, a switch such as a transistor may be arranged at a node such as between the quenching element 202 and the APD 201 or between the photoelectric conversion unit 102 and the pixel signal processing unit 103, and the signal output to the pixel output signal line 113 may be controlled by switching the electrical connection and the non-connection. Alternatively, the signal output to the pixel output signal line 113 may be controlled by changing the value of the voltage VH or the voltage VL supplied to the photoelectric conversion unit 102 using a switch such as a transistor.

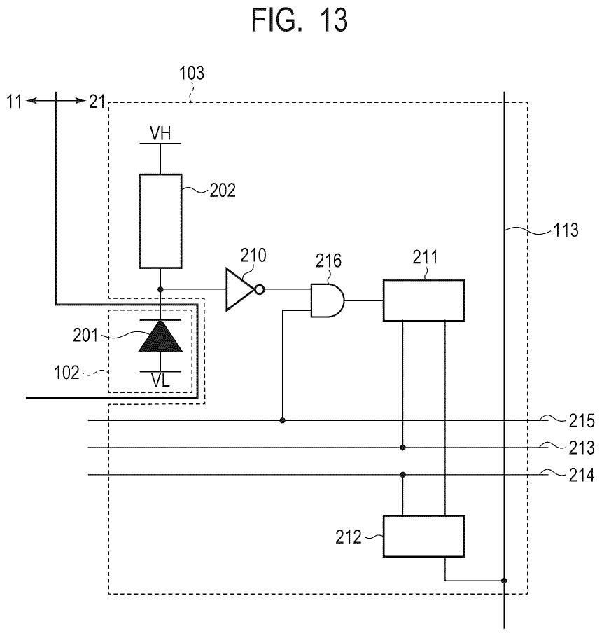

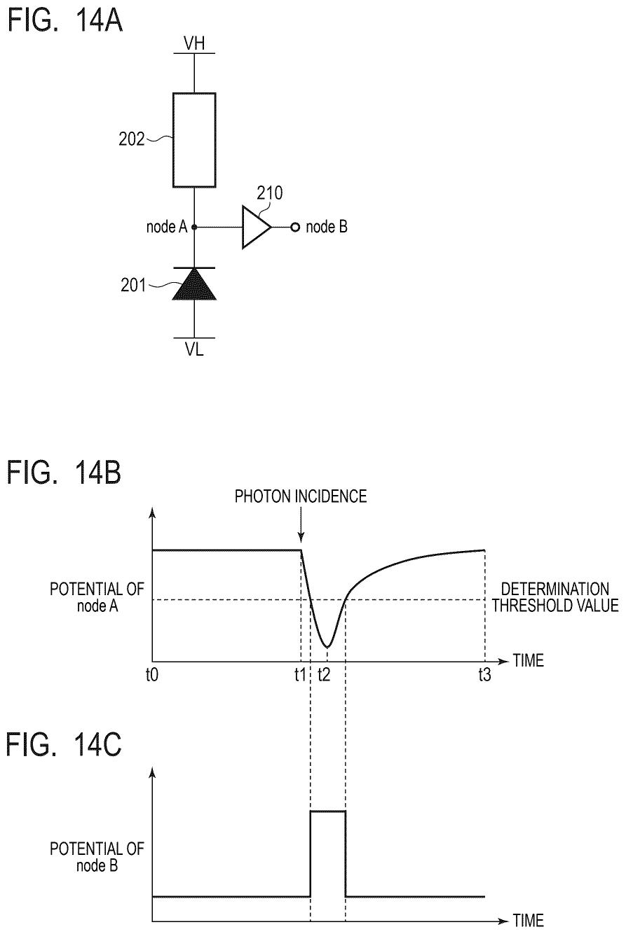

FIGS. 14A, 14B, and 14C are diagrams illustrating an operation of the APD 201 according to the present embodiment. FIG. 14A is a diagram illustrating the APD 201, the quenching element 202, and the waveform shaping unit 210 in FIG. 13. As illustrated in FIG. 14A, the connection node of the APD 201, the quenching element 202, and the input terminal of the waveform shaping unit 210 is referred to as node A. Further, as illustrated in FIG. 14A, an output side of the waveform shaping unit 210 is referred to as node B.

FIG. 14B is a graph illustrating a temporal change in the potential of node A in FIG. 14A. FIG. 14C is a graph illustrating a temporal change in the potential of node B in FIG. 14A. During a period from time t0 to time t1, the voltage VH-VL is applied to the APD 201 in FIG. 14A. When a photon enters the APD 201 at the time t1, avalanche multiplication occurs in the APD 201. As a result, an avalanche current flows through the quenching element 202, and the potential of the node A drops. Thereafter, the amount of potential drop further increases, and the voltage applied to the APD 201 gradually decreases. Then, at time t2, the avalanche multiplication in the APD 201 stops. Thereby, the voltage level of node A does not drop below a certain constant value. Then, during a period from the time t2 to time t3, a current that compensates for the voltage drop flows from the node of the voltage VH to the node A, and the node A is settled to the original potential at the time t3.

In the above-described process, the potential of node B becomes the high level in a period in which the potential of node A is lower than a certain threshold value. In this way, the waveform of the drop of the potential of the node A caused by the incidence of the photon is shaped by the waveform shaping unit 210 and output as a pulse to the node B.

According to the present embodiment, a photoelectric conversion device using an avalanche photodiode, which can be applied to the light detection unit 131 of the ranging device according to the first to fourth embodiments, is provided.

### Sixth Embodiment

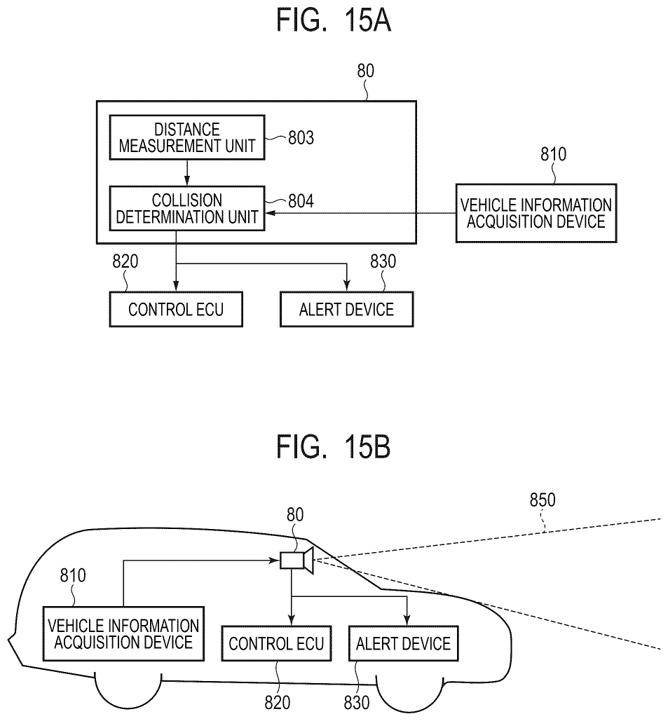

FIGS. 15A and 15B are block diagrams of equipment relating to an in-vehicle ranging device according to the present embodiment. Equipment 80 includes a distance measurement unit 803, which is an example of the ranging device of the above-described embodiments, and a signal processing device (processing device) that processes a signal from the distance measurement unit 803. The equipment 80 includes the distance measurement unit 803 that measures a distance to an object, and a collision determination unit 804 that determines whether or not there is a possibility of collision based on the measured distance. The distance measurement unit 803 is an example of a distance information acquisition unit that obtains distance information to the object. That is, the distance information is information on a distance to the object or the like. The collision determination unit 804 may determine the collision possibility using the distance information.

The equipment 80 is connected to a vehicle information acquisition device 810, and can obtain vehicle information such as a vehicle speed, a yaw rate, and a steering angle. Further, the equipment 80 is connected to a control ECU 820 which is a control device that outputs a control signal for generating a braking force to the vehicle based on the determination result of the collision determination unit 804. The equipment 80 is also connected to an alert device 830 that issues an alert to the driver based on the determination result of the collision determination unit 804. For example, when the collision possibility is high as the determination result of the collision determination unit 804, the control ECU 820 performs vehicle control to avoid collision or reduce damage by braking, returning an accelerator, suppressing engine output, or the like. The alert device 830 alerts the user by sounding an alarm, displaying alert information on a screen of a car navigation system or the like, or giving vibration to a seat belt or a steering wheel. These devices of the equipment 80 function as a movable body control unit that controls the operation of controlling the vehicle as described above.

In the present embodiment, ranging is performed in an area around the vehicle, for example, a front area or a rear area, by the equipment 80. FIG. 15B illustrates equipment when ranging is performed in the front area of the vehicle (ranging area 850). The vehicle information acquisition device 810 as a ranging control unit sends an instruction to the equipment 80 or the distance measurement unit 803 to perform the ranging operation. With such a configuration, the accuracy of distance measurement can be further improved.

Although the example of control for avoiding a collision to another vehicle has been described above, the embodiment is applicable to automatic driving control for following another vehicle, automatic driving control for not going out of a traffic lane, or the like. Furthermore, the equipment is not limited to a vehicle such as an automobile and can be applied to a movable body (movable apparatus) such as a ship, an airplane, a satellite, an industrial robot and a consumer use robot, or the like, for example. In addition, the equipment can be widely applied to equipment which utilizes object recognition or biometric authentication, such as an intelligent transportation system (ITS), a surveillance system, or the like without being limited to movable bodies.

### Modified Embodiments

The present disclosure is not limited to the above embodiments, and various modifications are possible. For example, an example in which some of the configurations of any one of the embodiments are added to other embodiments and an example in which some of the configurations of any one of the embodiments are replaced with some of the configurations of other embodiments are also embodiments of the present disclosure.

The disclosure of this specification includes a complementary set of the concepts described in this specification. That is, for example, if a description of “A is B” (A=B) is provided in this specification, this specification is intended to disclose or suggest that “A is not B” even if a description of “A is not B” (A B) is omitted. This is because it is assumed that “A is not B” is considered when “A is B” is described.

Embodiment(s) of the disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

It should be noted that any of the embodiments described above is merely an example of an embodiment for carrying out the present disclosure, and the technical scope of the present disclosure should not be construed as being limited by the embodiments. That is, the present disclosure can be implemented in various forms without departing from the technical idea or the main features thereof.

According to the present disclosure, a photoelectric conversion device and a method of controlling a photoelectric conversion device capable of reducing power consumption are provided.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-212996, filed Dec. 18, 2023, which is hereby incorporated by reference herein in its entirety.

What is claimed is:

1. A conversion device comprising:
a light detection unit including a photoelectric conversion element;
a control unit configured to control the light detection unit and a light source device; and
a processing unit configured to process a signal indicating a detection result of incident light to the light detection unit,
wherein in a first measurement, the control unit controls the light source device so that first pulsed light of a first light emission number is emitted from the light source device, and controls the light detection unit so as to detect light incident on the light detection unit in a first time window corresponding to a first distance,
wherein in the first measurement, the processing unit calculates a logical sum on first signals that are output from the light detection unit and indicate detection results to output a first light detection frame constituted by a 1-bit signal, the number of the first signals corresponding to the first light emission number,
wherein in a second measurement, the control unit controls the light source device so that second pulsed light of a second light emission number is emitted from the light source device, and controls the light detection unit so as to detect light incident on the light detection unit in a second time window corresponding to a second distance, and
wherein in the second measurement, the processing unit calculates a logical sum on second signals that are output from the light detection unit and indicate detection results to output a second light detection frame constituted by a 1-bit signal, the number of the second signals corresponding to the second light emission number.

2. The conversion device according to claim 1 further comprising a setting unit configured to set the first light emission number and the second light emission number,
wherein the setting unit sets the first light emission number based on the first distance and sets the second light emission number based on the second distance.

3. The conversion device according to claim 2, wherein the setting unit sets the first light emission number and the second light emission number by referring to a table indicating a relationship between a distance and a light emission number.

4. The conversion device according to claim 3, wherein the table is configured to include a section in which the light emission number is proportional to a square of the distance.

5. The conversion device according to claim 3, wherein the table is configured to include a section in which the light emission number changes stepwise with respect to the distance.

6. The conversion device according to claim 2, wherein the setting unit sets the first light emission number and the second light emission number using a formula indicating a relationship between a distance and a light emission number.

7. The conversion device according to claim 2 further comprising an acquisition device configured to acquire noise information indicating noise received by the light detection unit,
wherein the setting unit sets the first light emission number and the second light emission number further based on the noise information.

8. The conversion device according to claim 7, wherein the acquisition device acquires a light amount around the photoelectric conversion device as the noise information.

9. The conversion device according to claim 2 further comprising a surveillance device configured to surveille a predetermined surveillance range,
wherein the setting unit sets the first light emission number and the second light emission number further based on a surveillance result by the surveillance device.

10. The conversion device according to claim 2 further comprising a surveillance device configured to surveille a predetermined surveillance range,
wherein the control unit switches operation states of the light detection unit and the light source device based on a surveillance result by the surveillance device.

11. The conversion device according to claim 2, wherein the setting unit sets the first light emission number and the second light emission number such that a signal-to-noise ratio is included in a predetermined range at the first distance and the second distance.

12. The conversion device according to claim 2, wherein the setting unit sets the first light emission number and the second light emission number such that a signal-to-noise ratio is included in a range of 0.7 to 1.4 at the first distance and the second distance.

13. The conversion device according to claim 2, wherein the setting unit sets the first light emission number and the second light emission number such that a signal-to-noise ratio is included in a range of 1.0 to 1.2 at the first distance and the second distance.

14. The conversion device according to claim 1,
wherein the second light emission number is greater than the first light emission number, and
wherein the second distance is greater than the first distance.

15. The conversion device according to claim 1, wherein the control unit sets a length of an acquisition period of the first light detection frame based on the first light emission number, and sets a length of an acquisition period of the second light detection frame based on the second light emission number.

16. The conversion device according to claim 15,
wherein the second light emission number is greater than the first light emission number, and
wherein the acquisition period of the second light detection frame is longer than the acquisition period of the first light detection frame.

17. The conversion device according to claim 1, wherein the control unit sets a length of an acquisition period of the first light detection frame and a length of an acquisition period of the second light detection frame to be the same.

18. A ranging device comprising:
the conversion device according to claim 1; and
a calculation unit configured to acquire distance information from a signal based on the first light detection frame and the second light detection frame.

19. A movable body comprising:
the ranging device according to claim 18; and
a movable body control unit configured to control the movable body based on the distance information.

20. A method of controlling a conversion device having a light detection unit including a photoelectric conversion element, comprising:
detecting light incident on the light detection unit in a first time window corresponding to a first distance, when first pulsed light of a first light emission number is emitted from a light source device;
outputting a first light detection frame constituted by a 1-bit signal by calculating a logical sum on first signals that are output from the light detection unit and indicate detection results, the number of the first signals corresponding to the first light emission number;
detecting light incident on the light detection unit in a second time window corresponding to a second distance, when second pulsed light of a second light emission number is emitted from the light source device; and
outputting a second light detection frame constituted by a 1-bit signal by calculating a logical sum on second signals that are output from the light detection unit and indicate detection results, the number of the second signals corresponding to the second light emission number.
